(19) United States
(12) Patent Application Publication
(10) Pub. No.: US 2009/0121251 A1
(43) Pub. Date: May 14, 2009

(54) Siloxane-hydantoin copolymer, optoelectronic device encapsulated therewith and method

(75) Inventors: Sergei Kniajanski, Clifton Park, NY (US); Deborah Ann Haitko, Schenectady, NY (US)

Correspondence Address: Fay Sharpe LLP, 1228 Euclid Avenue, 5th Floor, The Halle Building, Cleveland, OH, 44115, US

(73) Assignee: Lumination LLC

(21) Appl. No.: 11/880,684

(22) Filed: Nov. 13, 2007

(51) Int. Cl. H01L 33/00; H01L 21/00; C08G 77/14

(52) U.S. Cl. 257/99; 438/26; 528/27; 257/E33.001; 257/E21.001

(57) ABSTRACT

The invention provides a siloxane-hydantoin copolymer, an optoelectronic device encapsulated therewith, and methods thereof. The siloxane-hydantoin copolymer comprises a unit selected from the group consisting of Y¹—O_{1/2} and O_{1/2—Y}²—O_{1/2}, wherein Y¹ and Y² contain a hydantoin structure or derivative thereof. The new material exhibits improved properties such as high optical transparency, high refractive index, superior UV and thermal stability, and good processability, among others.

### BACKGROUND OF THE INVENTION

The present invention is related to a siloxane-hydantoin copolymer, and optoelectronic device encapsulated therewith. More particularly, the siloxane-hydantoin copolymer comprises a unit selected from the group consisting of Y₁—O_{1/2} and O_{1/2}—Y₂—O_{1/2}, wherein Y¹ and Y² contain a hydantoin structure or derivative thereof.

It remains a challenge to design practical and cost effective encapsulating materials for optoelectronic devices such as UV LED products. The basic requirements for UV LED include, for example, thermal and UV stability for thousands of hours; optical transparency at 380-410 nm higher than 85%; refractive index higher than 1.5; processability at temperatures lower than 160° C.; and cost effectiveness, among others.

Many encapsulant candidates show unsatisfactory performance. For example, Teflon® is one of the most stable materials toward temperature and UV radiation, but its disadvantages are high cost, low transparency, and low refractive index.

Silicones such as polydimethylsiloxane (PDMS) have been used as encapsulant material for LED, as well as interface materials between the chip and encapsulant of an LED to offset the CTE mismatch of the chip with the encapsulant. For example, U.S. Pat. No. 6,407,411 to Wojnarowski et al. discloses a LED lead frame packaging assembly that includes a thermally conducting, electrically insulating material that enhances the thermal conduction and structural integrity of the assembly, a silicone encapsulant material, and an integral ESD material that reduces electrostatic discharge. The thermally conducting, electrically insulating material creates an electrically insulating, thermally conductive path in the lead frame assembly for dissipation of power and also acts as a mounting structure for the soft silicone encapsulant material. The silicone can be a crosslinked silicone polymer, e.g., polydimethylsiloxane or any other UV-resistant silicone polymers and copolymers. The silicone may be of many varieties made by General Electric of Waterford, N.Y. now Momentive, etc and many others, including Dow Corning. U.S. Pat. No. 6,541,800 to Barnett et al. discloses a LED package comprising an anode, a cathode coupled to the anode, an LED die coupled to the cathode and the anode, a lens coupled to the anode, and a viscous or silicone material located in a cavity defined by the lens, the cathode, and the anode. The viscous or silicone material may be a gel, a grease, a non-resilient material, or a non-liquid material. However, silicone exhibits drawbacks such as low refractive index and unavailability for transfer molding.

A LED encapsulant made of transparent epoxy resin is disclosed in U.S. Pat. No. 6,921,926 to Hsu. In the patent, the LED package comprises a plate-like first terminal made of an electrically conductive metal; a second terminal made of the electrically conductive metal and located at a side of the first terminal and spaced apart from the first terminal with a predetermined space; an LED die having a bottom bonded on a top surface of the first terminal such that an electrode located on the bottom of the die is electrically connected to the first terminal; a reflecting ring made of opaque white plastic and formed on the top surface of the first terminal by means of the molding technique to surround the die, the reflecting ring being provided with an upward sloping inner surface; and a conductive wire connected the other electrode on a top surface of the die to a top surface of the second terminal. The encapsulant made of insulated transparent epoxy resin encapsulates all the exposed surfaces of the die, the reflecting ring, the conductive wire, and other parts. However, epoxy based materials cannot be ultimately stable toward combined thermal and UV effect of the LED chip. Epoxy resins based on hydantoin, isocyanurate or barbiturate rings, while being of refractive index higher than 1.5, cost effective, transparent and well processed, also have shown a lack of thermal and UV stability in the long term.

Advantageously, the present invention provides a novel class of encapsulating material substantially free of epoxy groups in its structure, and its application in the construction of an optoelectronic device, as well. The material exhibits improved properties such as high optical transparency, high refractive index, superior UV and thermal stability, and good process capability, among other properties.

### BRIEF DESCRIPTION OF THE INVENTION

One aspect of the present exemplary embodiment is to provide a siloxane-hydantoin copolymer comprising a unit selected from the group consisting of Y¹—O_{1/2} and O_{1/2}—Y₂—O_{1/2}, wherein Y₁ and Y² contain a hydantoin structure or derivative thereof.

Another aspect of the present exemplary embodiment is to provide an optoelectronic device comprising a radiation source and an encapsulant, which includes a siloxane-hydantoin copolymer comprising a unit selected from the group consisting of Y¹—O_{1/2} and O_{1/2}—Y²—O_{1/2}, wherein Y¹ and Y² contain a hydantoin structure or derivative thereof.

Still another aspect of the present exemplary embodiment is to provide a method of preparing an optoelectronic device, which comprises (i) providing a radiation source, and (ii) encapsulating the radiation source with a siloxane-hydantoin copolymer comprising a unit selected from the group consisting of Y¹—O_{1/2} and O_{1/2}—Y²—O_{1/2}, wherein Y¹ and Y² contain a hydantoin structure or derivative thereof.

### BRIEF DESCRIPTION OF THE DRAWINGS

FIG. 1 shows a schematic diagram of a LED device according to an embodiment of the present invention;

FIG. 2 shows a schematic diagram of a LED array on a substrate according to one embodiment of the present invention;

FIG. 3 shows a schematic diagram of a LED device according to another embodiment of the present invention; and

FIG. 4 shows a schematic diagram of a vertical cavity surface emitting laser device according to still another embodiment of the present invention.

### DETAILED DESCRIPTION OF THE INVENTION

It is to be understood herein, that if a “range” or “group” is mentioned with respect to a particular characteristic of the present disclosure, for example, percentage, chemical species, amount, temperature, and other parameters, it relates to and explicitly incorporates herein each and every specific member and combination of sub-ranges or sub-groups therein whatsoever. Thus, any specified range or group is to be understood as a shorthand way of referring to each and every member of a range or group individually as well as each and every possible sub-range or sub-group encompassed therein; and similarly with respect to any sub-ranges or sub-groups therein.

In preferred exemplary embodiments, the optoelectronic devices of the invention include blue/ultraviolet LEDs and lasers. The siloxane-hydantoin copolymer can be directly deposited on LED or laser chips to aid in the optical out-coupling.

The weight average molecular weight (Mw) of the siloxane-hydantoin copolymer is generally within the range of from about 5,000 to about 250,000, preferably within the range of from about 60,000 to about 200,000, and more preferably within the range of from about 100,000 to about 150,000.

The glass transition temperature (Tg) of the siloxane-hydantoin copolymer is generally within the range of from about 35° C. to about 150° C., preferably within the range of from about 60° C. to about 140° C., and more preferably within the range of from about 115° C. to about 135° C.

The siloxane-hydantoin copolymer generally exhibits high transparency for radiation with wavelength in the range of from about 380 nm to about 1200 nm, preferably in the range of from about 380 nm to about 700 nm, and more preferably within the range of from about 380 nm to about 470 nm, such as 400 nm.

The optical transmittance of the siloxane-hydantoin copolymer is generally at least 80%, preferably at least 85%, and more preferably at least 92%, such as 90%, over a broad range of radiation, such as between 340 and 700 nm, preferably 400 nm.

The refractive index of the siloxane-hydantoin copolymer is generally within the range of from about 1.500 to about 1.620, preferably within the range of from about 1.550 to about 1.620, and more preferably within the range of from about 1.570 to about 1.620, such as 1.585, over a broad range of radiation, such as 400 nm radiation.

The siloxane-hydantoin copolymer of the invention is generally thermally stable and UV stable. The material exhibits thermal stability under temperature of at least 350° C., preferably under temperature of at least 300° C., and more preferably under temperature of at least 200° C. It can remain thermally and UV stable for at least 50,000 hours, preferably at least 30,000 hours, and more preferably at least 15,000 hours.

In embodiments, the siloxane-hydantoin copolymer flows above the Tg so that it can easily encapsulate an optoelectronic device such as LED lighting product. The viscosity of the copolymer at a temperature equal to or above the Tg is generally within the range of from about 500 cps to about 75,000 cps, preferably within the range of from about 1,000 cps to about 40,000 cps, and more preferably within the range of from about 3,000 cps to about 10,000 cps.

In various exemplary embodiments, the siloxane-hydantoin copolymer can be defined based on the “MDTQ” nomenclature, which is a shorthand nomenclature system known to those of ordinary skill in the art. For example, the siloxane-hydantoin copolymer can comprise an empirical formula of:

MₐD_{b}T_{c}Q_{d}GₑH_{f}

wherein a, b, c, d, e, and f are the relative amounts of the units M, D, T, Q, G, and H respectively; a≧0; b≧0; c≧0; d≧0; e≧0; f≧0; a+b+c+d+e+f=1.0; M is R¹R²R³SiO_{1/2}; D is R⁴R⁵SiO_{2/2}; T is R⁶SiO_{3/2}; and Q is SiO_{4/2}; or MDTQ can be drawn as structures (without any implied limitation of stereochemistry):

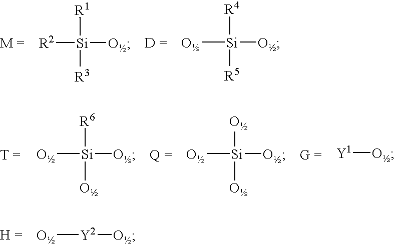

wherein R₁, R₂, R₃, R₄, R₅, and R₆ can be each independently selected from H, hydroxyl, halo groups, alkoxy groups, monovalent acyclic hydrocarbon radicals, monovalent alicyclic hydrocarbon radicals, and monovalent aromatic hydrocarbon radicals; Y¹ is a monovalent group comprising one or more hydantoin cycles or derivatives thereof; and Y² is a divalent group comprising one or more hydantoin cycles or derivatives thereof. In exemplified embodiments, hydantoin derivatives incude mono- or dialkyl-substituted or hydroxyalkyl-substituted hydantoin. The structure of hydantoin is represented by the formula below. In hydantoin derivatives, the two hydrogen atoms bonded to the two nitrogen atoms and the two hydrogen atoms bonded to the carbon atom may be completely or partially replaced with any other group(s) such as alkyl and hydroxyalkyl.

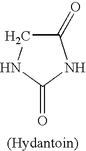

As used herein, the terminology “monovalent acyclic hydrocarbon radical” means a monovalent straight chain or branched hydrocarbon radical, preferably containing from 2 to 12 carbon atoms per radical, which may be saturated or unsaturated and which may be optionally substituted or interrupted with one or more functional groups, such as, for example, amino, carboxyl, cyano, hydroxy, halo, mercapto, and oxy. Suitable monovalent acyclic hydrocarbon radicals include, for example, alkyl such as methyl, ethyl, propyl, sec-butyl, tert-butyl, octyl, and dodecyl; alkoxy such as methoxy or ethoxy; hydroxyalkyl such as hydroxymethyl, hydroxyethyl or hydroxypropyl; alkenyl such as ethenyl or propenyl; cyanoalkyl such as cyanomethyl or cyanoethyl; carboxyalkyl such as carboxymethyl or carboxypropyl; alkylamido such as methylamido or dodecylamido; and haloalkyl such as chloromethyl, 2-fluoropropyl, 2,2-difluropropyl or 3,3,3-trifluoropropyl, as well as monovalent glycidyl ether radicals. As used herein the terminology “monovalent glycidyl ether radical” means a monovalent radical containing at least one oxygen atom substituted with at least one glycidyl-containing moiety, such as, for example, glycidyloxy or glycidylalkyloxy, including, for example, glycidylethyloxy or glycidylpropyloxy.

As used herein, the terminology “monovalent alicyclic hydrocarbon radical” means a monovalent radical containing one or more saturated hydrocarbon rings, preferably containing from 4 to 10 carbon atoms per ring, per radical which may optionally be substituted on one or more of the rings with one or more functional groups, such as for example, alkyl, halo or alkenyl groups, each preferably containing from 2 to 6 carbon atoms per group, and which, in the case of two or more rings, may be fused rings. Suitable monovalent alicyclic hydrocarbon radicals include, for example, cyclohexyl and cyclooctyl.

As used herein, the terminology “monovalent aromatic hydrocarbon radical” means a monovalent hydrocarbon radical containing at least one aromatic ring per radical, which may optionally be substituted on the aromatic ring with one or more functional groups, such as for example, alkyl, halo or alkenyl groups, each preferably containing from 2 to 6 carbon atoms per group. Suitable monovalent aromatic hydrocarbon radicals include, for example, phenyl, benzyl, tolyl, and 2,4,6-trimethylphenyl.

Although generally the “a” value is equal to or greater than 0, preferably the “a” value is less than 0.01, and more preferably the “a” value is less than 0.001, for example, the “a” value may be so close to zero that it is ignorable in the siloxane-hydantoin copolymer MₐD_{b}T_{c}Q_{d}GₑH_{f}. Examples of M unit include, but are not limited to, the following structures:

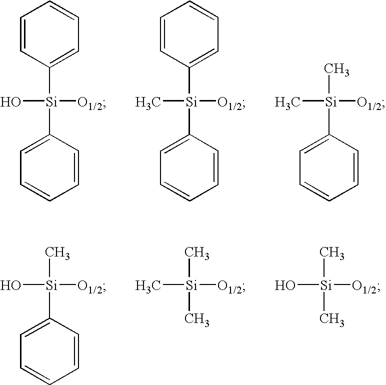

and the mixture thereof.

The “b” value may vary within the range of from about 0.3 to about 0.9, for example, the “b” value may be about 0.66 in the siloxane-hydantoin copolymer MₐD_{b}T_{c}Q_{d}GₑH_{f}. Examples of D unit include, but are not limited to, the following structures:

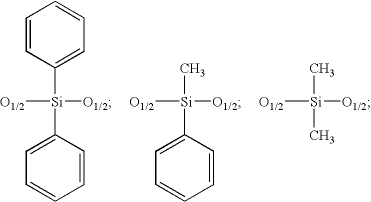

and the mixture thereof.

Preferably the “c” value is within the range of from about 0 to about 0.25, and more preferably the “c” value is within the range of from about 0.05 to about 0.15, for example, the “c” value may be close to or equal to zero in the siloxane-hydantoin copolymer MₐD_{b}T_{c}Q_{d}GₑH_{f}. Examples of T unit include, but are not limited to, the following structures:

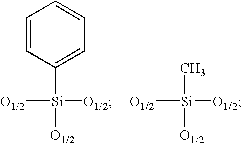

and the mixture thereof.

Although generally the “d” value is equal to or greater than 0, preferably the “d” value is less than 0.01, and more preferably the “d” value is less than 0.001, for example, the “d” value may be close to or equal to zero in the siloxane-hydantoin copolymer MₐD_{b}T_{c}Q_{d}GₑH_{f}.

Although generally the “e” value is equal to or greater than 0, preferably the “e” value is less than 0.01, and more preferably the “e” value is less than 0.01, for example, the “e” value may be so close to zero that it is ignorable in the siloxane-hydantoin copolymer MₐD_{b}T_{c}Q_{d}GₑH_{f}. Examples of G unit include, but are not limited to, the following structures:

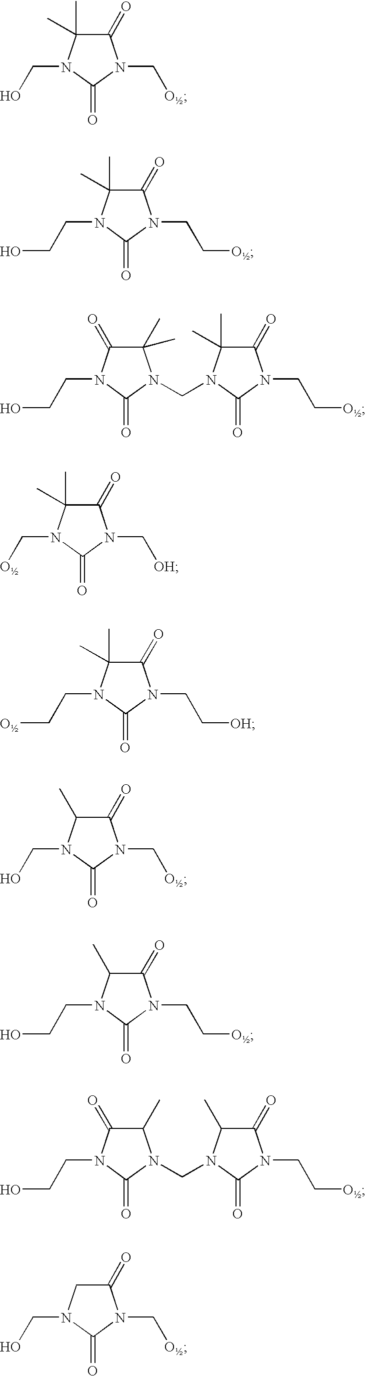

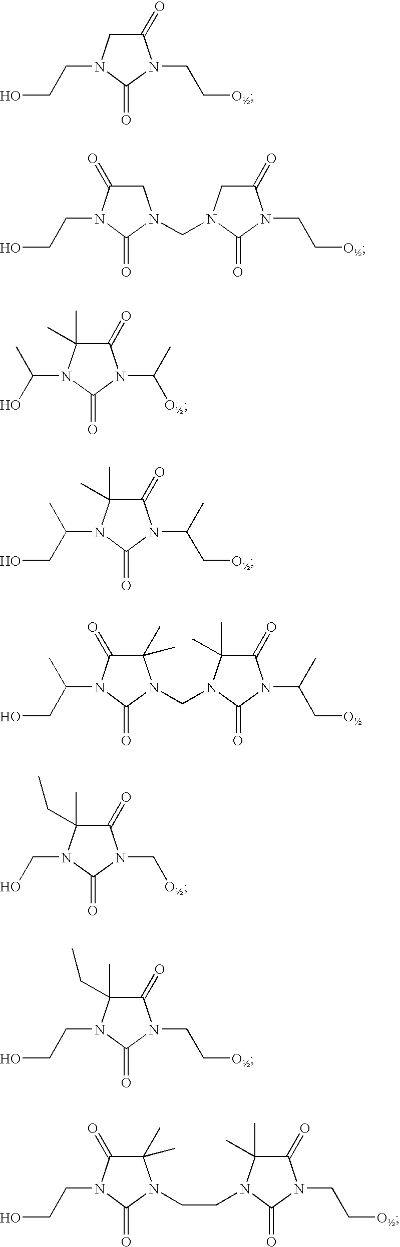

and the like, and the mixture thereof.

The “f” value is within the range of from about 0.1 to about 0.5. For example, the “f” value may be about 0.33 in the siloxane-hydantoin copolymer MₐD_{b}T_{c}Q_{d}GₑH_{f}. Examples of H unit include, but are not limited to, the following structures:

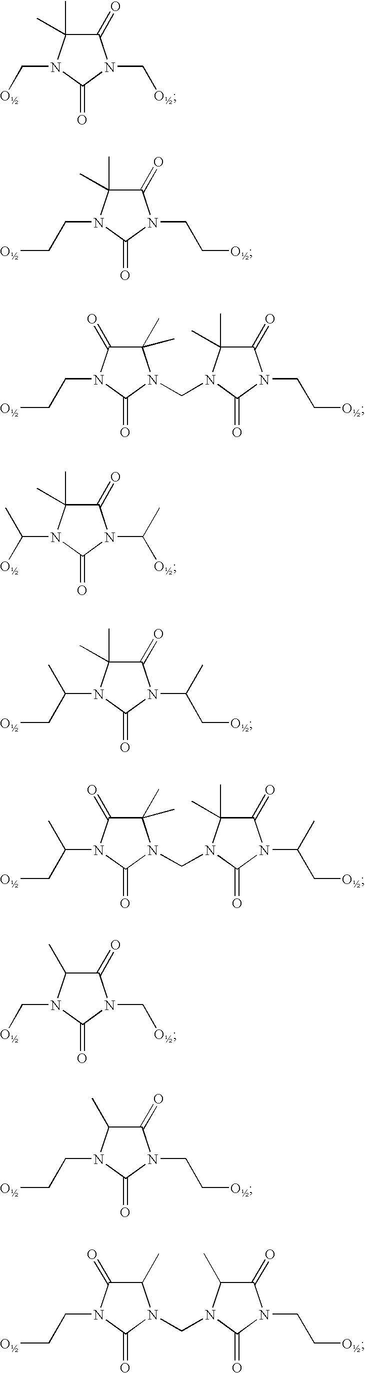

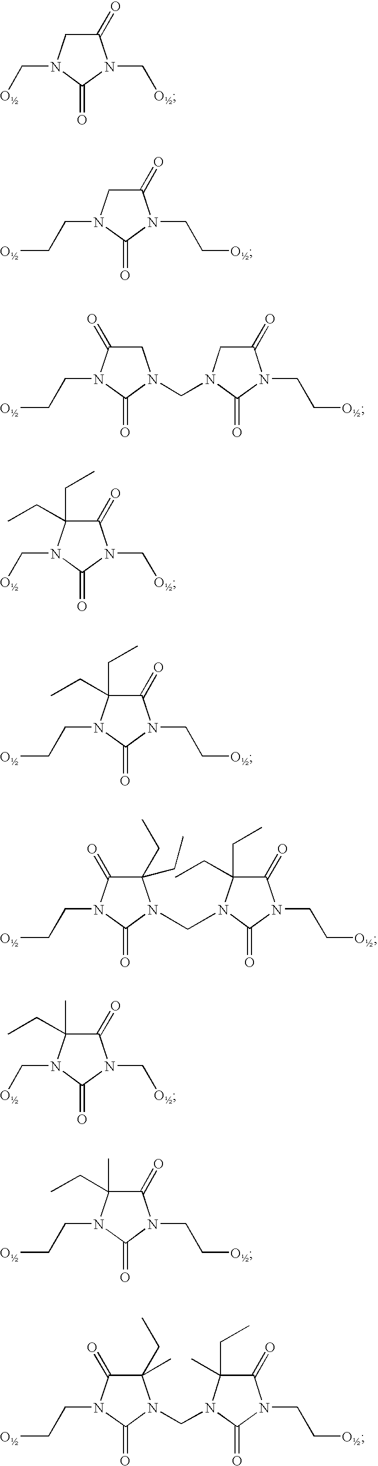

and the like, and the mixture thereof.

In various exemplary embodiments, the siloxane-hydantoin copolymer comprises a linear chain, a cyclic chain, or combination thereof. The “M” and/or “G” unit (terminal unit) may be located at the ends of a linear chain, if any. For example, the copolymer units may comprise “D” unit and “H” unit in a molar ratio D:H within the range of from about 10:1 to about 1:1, preferably within the range of from about 6:1 to about 1:1, and more preferably within the range of from about 4:1 to about 1:1, such as 2:1. In embodiments, the siloxane-hydantoin copolymer comprises units as shown below:

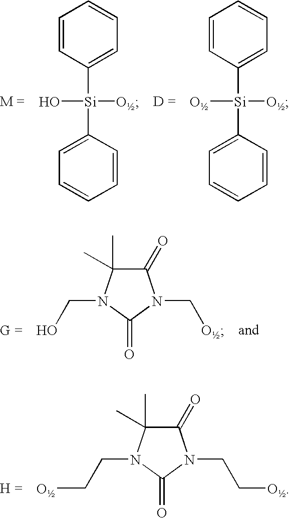

In an embodiment, the siloxane-hydantoin copolymer can be represented by the general formula below:

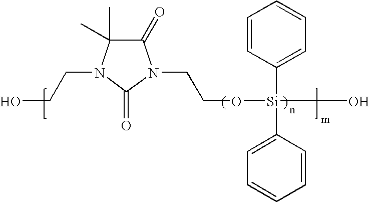

wherein n is an integer from 1 to 4; and m is generally within the range of from about 10 to about 500, preferably within the range of from about 100 to about 400, and more preferably within the range of from about 160 to about 300.

In various embodiments, the copolymers of the invention are composed of ˜100% alternated bivalent units derived from hydantoin monomers and bivalent units derived from siloxane monomers, with some inclusions of trivalent units. Siloxane monomers are preferably diphenylsiloxane units rather than methylsiloxanes, because of some disadvatages associated with the latter, such as low refractive index, low Tg, and low hydrolytic stability of SiMe₂—O—C linkage.

Trivalent or tetravalent units are derived from silanes or siloxanes, which contain three or more reactive groups, like PhSiCl₃, SiCl₄ or Cl₂PhSi—O—SiCl₂Ph. Trivalent units increase M_{w}, Tg, point of flow, thermal stability, even refractive index, but make the polymer less process capable. In addition, without trivalent units it's hard to make high Tg product. Therefore, there is a low limit of the content of trivalent units, after which the material becomes incapable to process.

The siloxane-hydantoin copolymer can be synthesized based on various known polymerization techniques, or obtained from a commercial source. For example, the copolymer can be prepared based on either hydrolytic condensation or non-hydrolytic condensation. The polycondensation reaction between, for example, organofunctional silanes or oligosiloxanes, leads to the formation of siloxane bond and elimination of a low molecular weight byproduct. The polycondensation of low molecular weight siloxanol oils gives water as the byproduct. Many non-hydrolytic condensation processes may also be employed. The formation of Si—O—Si bond, Si—O—Y¹ bond, Si—O—Y² bond, Y¹—O—Y² bond, Y¹—O—Y¹ bond, and Y²—O—Y² bond may be accomplished by the reactions illustrated below. It is understood that

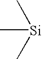

and/or

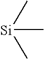

can be replaced with Y¹ and or Y².
(1) The reaction of an organohalosilane with an organoalkoxysilane:

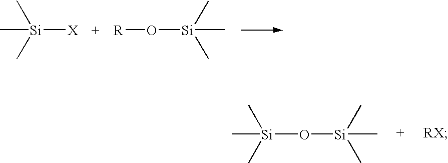

(2) The reaction of an organohalosilane with an organoacyloxysilane:

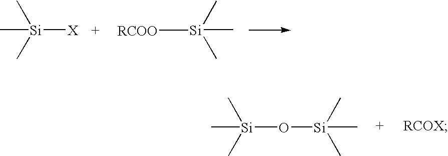

(3) The reaction of an organohalosilane with an organosilanol:

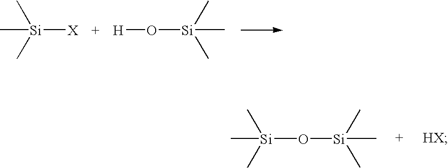

(4) The reaction of an organohalosilane with a metal (M) silanolate:

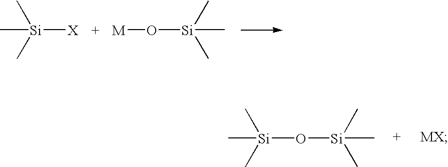

(5) The reaction of an organo-hydrosilane with an organosilanol:

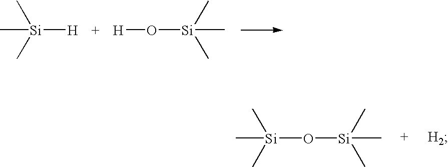

(6) The self-reaction of two organoalkoxysilanes:

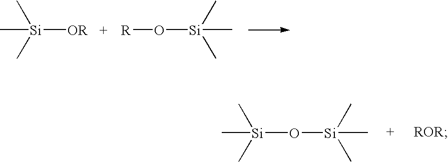

(7) The reaction of an organoalkoxysilane with an organoacyloxysilane:

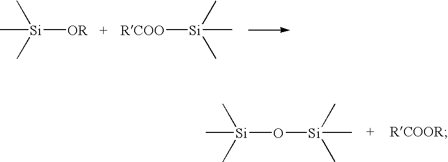

(8) The reaction of an organoalkoxysilane with an organosilanol:

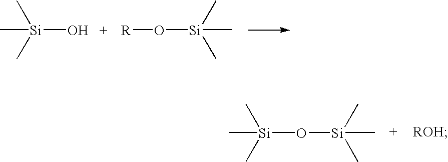

(9) The reaction of an organoaminosilane with an organosilanol:

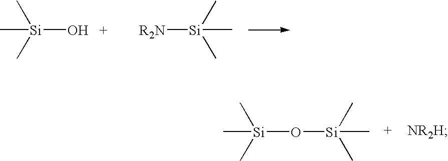

(10) The reaction of an organoacyloxysilane with a metal (M) silanolate:

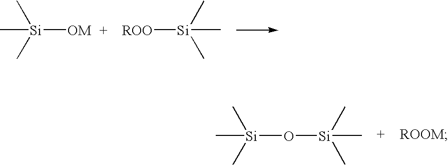

and
(11) The reaction of an organoacyloxysilane with an organosilanol:

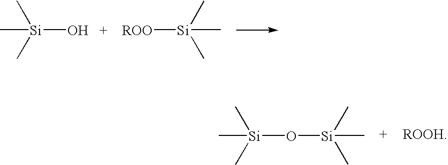

Those reactions can also be used for the formation of siloxane networks via a crosslinking process. Many of the above processes require the presence of catalyst such as protic acids, Lewis acids, organic and inorganic bases, metal salts and organometalic complexes. (See, for example, (a) “The Siloxane Bond” Ed. Voronkov, M. G.; Mileshkevich, V. P.; Yuzhelevskii, Yu. A. Consultant Bureau, New York and London, 1978; and (b) Noll, W. “Chemistry and Technology of Silicones”, Academia Press, New York, 1968).

In exemplary embodiments, MDTQ precursors and oligomers comprising one or more Si—X bonds (X is a halogen) such as a dichlorooligodiphenylsiloxane, can be condensed with HG precursors and oligomers comprising one or two —OH groups such as a diethanol hydantoin, to produce the siloxane-hydantoin copolymer. Examples of such MDTQ or HG precursors and oligomers include, but are not limited to, the following reagents:

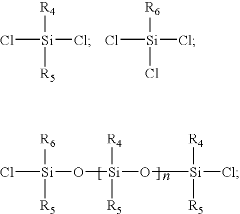

Y¹—OH; HO—Y²—OH; and the like;

wherein n is an integer and n≧0; R₄, R₅, R₆, Y¹, and Y² are defined as above.

Specific examples of MDTQ or HG precursors and oligomers include, but are not limited to, the following reagents:

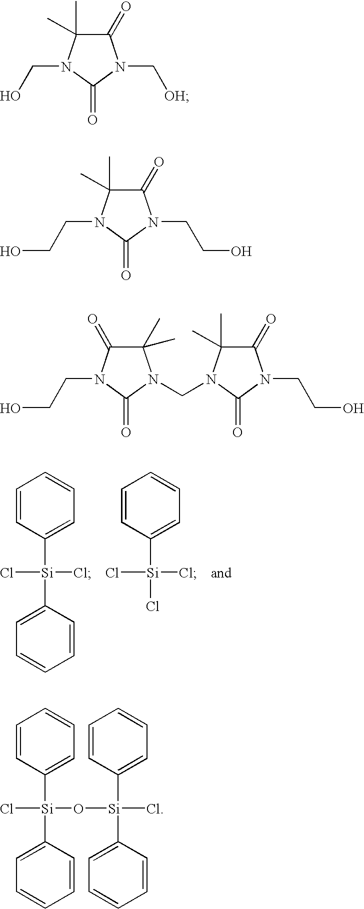

In an embodiment, the combination of the following MDTQ and HG precursors (as co-monomers) is used to produce the siloxane-hydantoin copolymer:

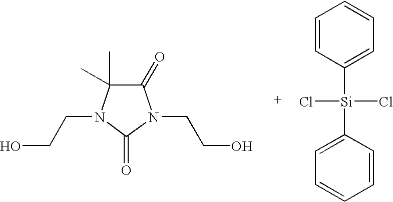

In another embodiment, the combination of the following MDTQ and HG precursors/oligomers (as co-monomers) is used to produce the siloxane-hydantoin copolymer:

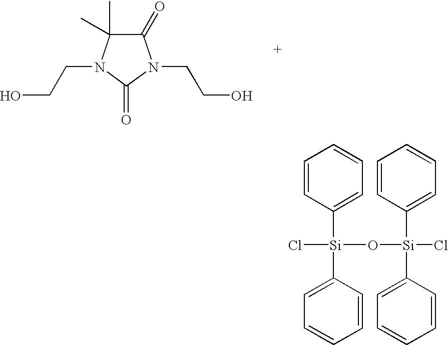

In still another embodiment, the combination of the following MDTQ and HG precursors/oligomers (as co-monomers) is used to produce the siloxane-hydantoin copolymer. M_{w} and Tg of the product can be improved significantly.

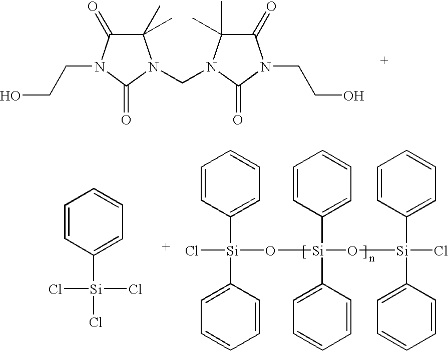

In various embodiments, the siloxane-hydantoin copolymer can be prepared in suitable solvent such as DMF in the presence of an amine compound such as NEt₃. The polymerization can be conducted at a temperature in the range of from about 15° C. to about 30° C. such as room temperature during a sufficient time period to maximize the yield, such as from about 0.5 hours to about 6 hours, for example about 2 hours. The reaction product can be isolated by subsequent filtration, solvent evaporation, precipitation into water, and drying.

In an embodiment, the linkage between hydantoin and siloxane units can be formed via polyaddition reaction, as for example shown below:

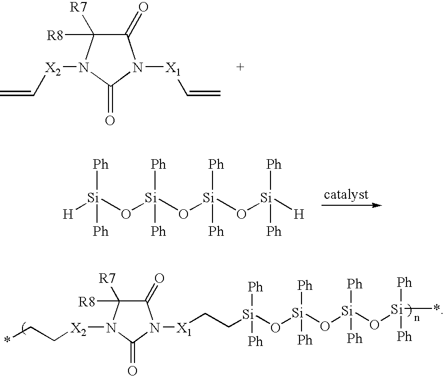

Optoelectronic device of the invention may be any solid-state or other electronic device for generating, modulating, transmitting, and sensing electromagnetic radiation in the ultraviolet, visible, or infrared portions of the spectrum. Optoelectronic devices, sometimes referred to as semiconductor devices or solid state devices, include, but are not limited to, light emitting diodes (LEDs), charge coupled-LED devices (CCDs), photodiodes, vertical cavity surface emitting lasers (VCSELs), phototransistors, photocouplers, opto-electronic couplers, and the like. However, it should be understood that the encapsulant formulation can also be used in devices other than an optoelectronic device, for example, logic and memory devices, such as microprocessors, ASICs, DRAMs and SRAMs, as well as electronic components, such as capacitors, inductors and resistors, among others.

The radiation source of the invention may be, for example, a light emitting diode (LED), a lamp, a laser, an organic emissive structure, an electron gun, or any other source of radiation. In preferred embodiments, the radiation source emits radiation, which excites the luminescent material such as phosphor, and thus causes the luminescent material to emit visible light. For example, the radiation source can emit visible light, radiation at less than 400 nm, such as UV or x-ray radiation, or any combinations thereof.

In embodiments, the radiation source comprises a LED chip that contains a p-n junction of any semiconductor layers capable of emitting the desired radiation. For example, the LED chip may contain any desired Group III-V compound semiconductor layers, such as GaAs, GaAlAs, GaN, InGaN, GaP, etc., or Group II-VI compound semiconductor layers such as ZnSe, ZnSSe, CdTe, etc., or Group IV-IV semiconductor layers, such as SiC. The LED chip may also contain other layers, such as cladding layers, waveguide layers and contact layers.

The present invention provides a method of preparing an optoelectronic device, which comprises (i) providing a radiation source, and (ii) encapsulating the radiation source with the siloxane-hydantoin copolymer as described above.

As a skilled artisan can appreciate, an optoelectronic device may comprise many parts that are made from a wide variety of organic or inorganic materials. For example, optoelectronic components may include lead frame, bond wire, solder, electrode, pad, contact layer, phosphor layer, and dielectric layer etc. These optoelectronic components may be made of or made from materials, for example, metals such as aluminum, gold, silver, tin-lead, nickel, copper, and iron, and their alloys; silicon; passivation coatings such as silicon dioxide and silicon nitride; aluminum nitride; alumina; fluorocarbon polymers such as polytetrafluoroethylene and polyvinylfluoride; polyamides such as Nylon; organic resins such as polyimide; polyesters; ceramics; plastic; and glass etc.

In various exemplary embodiments, the present invention provides an optoelectronic device comprising a radiation source, an encapsulant comprising the above siloxane-hydantoin copolymer, and a phosphor. A method of preparing such an optoelectronic device may comprise (i) providing a radiation source, (ii) encapsulating the radiation source with an encapsulant formulation comprising the above siloxane-hydantoin copolymer, and (iii) disposing at least one of the above phosphors adjacent to the radiation source, so that the phosphor is adapted to be excited by the radiation emitted from the radiation source.

A phosphor is a luminescent material that absorbs radiation energy in a portion of the electromagnetic spectrum and emits energy in another portion of the electromagnetic spectrum. Phosphors of one important class are crystalline inorganic compounds of high chemical purity and of controlled composition to which small quantities of other elements (called “activators”) have been added to convert them into efficient fluorescent materials. With the right combination of activators and inorganic compounds, the color of the emission can be controlled. Most useful and well-known phosphors emit radiation in the visible portion of the electromagnetic spectrum in response to excitation by electromagnetic radiation outside the visible range.

The phosphors of the present invention can be used in any lighting applications that match their chemical properties and photophysical properties, either alone, or in combination with other phosphors. For example, blends comprising the phosphors of the invention can be used to make white light emitting devices.

Any suitable phosphor material may be used with the LED chip. For example, a yellow emitting cerium doped yttrium aluminum garnet phosphor (YAG:Ce³⁺) may be used with a blue emitting InGaN active layer LED chip to produce a visible yellow and blue light output which appears white to a human observer. Other combinations of LED chips and phosphors may be used as desired. A detailed disclosure of a UV/blue LED-Phosphor Device with efficient conversion of UV/blue Light to visible light may be found in U.S. Pat. No. 5,813,752 (Singer) and U.S. Pat. No. 5,813,753 (Vriens).

To design an optoelectronic device that emits white light, a general approach is to combine a light emitting semiconductor and a phosphor, or simply “LED-phosphor system”. For example, U.S. Pat. No. 5,998,925 teaches that phosphor (Y_{0.4}Gd_{0.6})₃Al₅O₁₂:Ce can be used to convert a portion of a blue emitted light from a GaN die to yellow light. The overall emission of the LED device, consisting of blue GaN device generated light and yellow phosphor emitted light is a generally white light. Also, as discussed in chapter 10.4 of “The Blue Laser Diode” by S. Nakamura et al., pages 216-221 (Springer 1997), white light LEDs may be fabricated by forming a ceramic phosphor layer on the output surface of a blue light emitting semiconductor LED. The blue LED is an InGaN single quantum well LED and the phosphor is a cerium doped yttrium aluminum garnet (“YAG:Ce”), Y₃Al₅O₁₂:Ce³⁺. The blue light emitted by the LED excites the phosphor, causing it to emit yellow light. The blue light emitted by the LED is transmitted through the phosphor and is mixed with the yellow light emitted by the phosphor. The viewer perceives the mixture of blue and yellow light as white light.

Phosphor particles may be prepared from larger pieces of phosphor material by any grinding or pulverization method, such as ball milling using zirconia-toughened balls or jet milling. They also may be prepared by crystal growth from solution, and their size may be controlled by terminating the crystal growth at an appropriate time.

An exemplary phosphor is the cerium-doped yittrium aluminum oxide Y₃Al₅O₁₂ garnet (“YAG:Ce”). Other suitable phosphors are based on YAG doped with more than one type of rare earth ions, such as (Y_{1-x-y}GdₓCe_{y})₃Al₅O₁₂ (“YAG:Gd,Ce”), (Y₁₋ₓCeₓ)₃(Al_{5-y}Ga_{y})O₁₂ (“YAG:Ga,Ce”), (Y_{1-x-y}GdₓCe_{y})(Al_{5-z}Ga_{z})O₁₂ (“YAG:Gd,Ga,Ce”), and (Gd₁₋ₓCeₓ)Sc₂Al₃O₁₂ (“GSAG”), where 0≦x≦1, 0≦y≦1, 0≦z≦5, and x+y≦1. For example, the YAG:Gd,Ce phosphor shows an absorption of light in the wavelength range from about 390 nm to about 530 nm (i.e., the blue-green spectral region) and an emission of light in the wavelength range from about 490 nm to about 700 nm (i.e., the green-to-red spectral region). Related phosphors include Lu₃Al₅O₁₂ and Tb₂Al₅O₁₂, both doped with cerium. In addition, these cerium-doped garnet phosphors may also be additionally doped with small amounts of Pr (such as about 0.1-2 mole percent) to produce an additional enhancement of red emission. Still other ions may be incorporated into the phosphor to transfer energy from the emitted light to other activator ions in the phosphor host lattice as a way to increase the energy utilization. For example, when Sb³⁺ and Mn²⁺ ions exist in the same phosphor lattice, Sb³⁺ efficiently absorbs light in the blue region, which is not absorbed very efficiently by Mn²⁺, and transfers the energy to Mn²⁺ ion. Thus, a larger total amount of light from light emitting diode is absorbed by both ions, resulting in higher quantum efficiency.

Phosphors that can be efficiently excited by radiation of, for example, 300 nm to about 500 nm, are preferably used in the optoelectronic device. Non-limiting examples of blue light-emitting phosphors include BaMg₂Al₁₆O₂₇:Eu²⁺; Sr₅(PO₄)₁₀Cl₂:Eu²⁺; (Ba,Ca,Sr)(PO₄)₁₀(Cl,F)₂:Eu²⁺; (Ca,Ba,Sr)(Al,Ga)₂S₄:Eu²⁺; (Ba,Sr,Ca)₅(PO₄)₃(Cl,F,Br,OH):Eu²⁺,Mn²⁺,Sb³⁺; (Ba,Sr,Ca)MgAl₁₀O₁₇Eu²⁺,Mn²⁺; (Ba,Sr,Ca)BPO₅:Eu²⁺,Mn²⁺;(Sr,Ca)₁₀(PO₄)₆*nB₂O₃:Eu²⁺;2SrO*0.84P₂O₅*0.16B₂O₃:Eu²⁺; Sr₂Si₃O₈*2SrCl₂:Eu²⁺;Ba₃MgSi₂O₈:Eu²⁺;Sr₄Al₁₄O₂₅:Eu²⁺(SAE); BaAl₈O₁₃:Eu²⁺; and the like, and any combination thereof.

Non-limiting examples of blue-green light-emitting phosphors include Sr₄Al₁₄O₂₅:Eu²⁺;BaAl₈O₁₃:Eu²⁺;2SrO*0.84P₂O₅*0.16B₂O₃:Eu²⁺; (Ba,Sr,Ca)MgAl₁₀O₁₇:Eu²⁺,Mn²⁺;(Ba,Sr,Ca)₅(PO₄)₃(Cl,F,OH):Eu²⁺,Mn²⁺,Sb³⁺; and the like, and any combination thereof.

Non-limiting examples of green light-emitting phosphors include Ca₈Mg(SiO₄)₄Cl₂:Eu²⁺, Mn²⁺;GdBO₃:Ce³⁺, Tb³⁺;CeMgAl₁₁O₁₉:Tb³⁺; Y₂SiO₅:Ce³⁺, Tb³⁺; BaMg₂Al₂₇:Eu²⁺, Mn²⁺;(Ba,Sr,Ca)MgAl₁₀O₁₇:Eu²⁺,Mn²⁺(BAMn);(Ba,Sr,Ca)Al₂O₄:Eu²⁺; (Y,Gd,Lu,Sc,La)BO₃:Ce³⁺,Tb³⁺; Ca₈Mg(SiO₄)₄Cl₂:Eu²⁺,Mn²⁺; (Ba,Sr,Ca)₂SiO₄:Eu²⁺; (BA,Sr,Ca)₂(Mg,Zn)SiO₇:Eu²⁺; (Sr,Ca,Ba)(Al,Ga,In)₂S₄:Eu²⁺; (Y,Gd,Tb,La,Sm,Pr,Lu)₃(Al,Ga)₅O₁₂:Ce³⁺; (Ca,Sr)₈(Mg,Zn)(SiO₄)₄Cl₂: Eu²⁺(CASI); Na₂Gd₂B₂O₇:Ce³⁺; (Ba,Sr)₂(Ca,Mg,Zn)B₂O₆:K,Ce,Tb; and the like, and any combination thereof.

Non-limiting examples of yellow-orange light-emitting phosphors include (Ba,Ca,Sr)(PO₄)₁₀(Cl,F)₂:Eu²⁺,Mn²⁺; (Sr,Ca,Ba,Mg,Zn)₂P₂O₇:Eu²⁺,Mn²⁺(SPP); (Ca,Sr,Ba,Mg)₁₀(PO₄)₆(F,Cl,Br,OH):Eu²⁺,Mn²⁺(HALO);((Y,Lu,Gd,Tb)₁₋ₓScₓCe_{y})₂(Ca,Mg)₁₋ᵣ(Mg,Zn)₂₊ᵣSi_{z-q}Ge_{q}O_{12+δ}; and the like, and any combination thereof.

Non-limiting examples of red light-emitting phosphors include Y₂O₃:Bi³⁺,Eu³⁺; Sr₂P₂O₇:Eu²⁺,Mn²⁺; SrMgP₂O₇:Eu²⁺,Mn²⁺; (Y,Gd)(V,B)O₄:Eu³⁺; 3.5MgO.0.5MgF₂.GeO₂:Mn⁴⁺(magnesium fluorogermanate); (Gd,Y,Lu,La)₂O₃:Eu³⁺,Bi³⁺; (Gd,Y,Lu,La)₂O₂S:Eu³⁺,Bi³⁺;(Gd,Y,Lu,La)VO₄:Eu³⁺,Bi³⁺; (Ca,Sr)S:Eu²⁺,Ce³⁺; SrY₂S₄:Eu²⁺,Ce³⁺;CaLa₂S₄:Ce³⁺;(Ca,Sr)S:Eu²;3.5MgO*0.5MgF₂*GeO₂;Mn⁴⁺(MFG); (ba,Sr,Ca)MgP₂O₇:Eu²⁺,Mn²⁺; (Y,Lu)₂WO₆:Eu³⁺,Mo⁶⁺; (Ba,Sr,Ca)ₓSi_{y}N_{z}:Eu²⁺, Ce³⁺; (Ba,Sr,Ca,Mg)₃(Zn,Mg)Si₂O₈:Eu²⁺, Mn²⁺; and the like, and any combination thereof.

Other optional components in the encapsulant may include one or more refractive index modifiers. Non-limiting examples of suitable refractive index modifiers are compounds of Groups II, III, IV, V, and VI of the Periodic Table. Non-limiting examples are titanium oxide, hafnium oxide, aluminum oxide, gallium oxide, indium oxide, yttrium oxide, zirconium oxide, cerium oxide, zinc oxide, magnesium oxide, calcium oxide, lead oxide, zinc selenide, zinc sulphide, gallium nitride, silicon nitride, aluminum nitride, or alloys of two or more metals of Groups II, III, IV, V, and VI such as alloys made from Zn, Se, S, and Te.

Optional components in the encapsulant may also comprise coupling agents which in various embodiments may help the encapsulant epoxy resin bind to a matrix, such as a glass matrix, so as to form a strong bond such that premature failure does not occur. In a variety of exemplary embodiments, the coupling agent may have a formula as shown below:

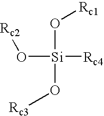

in which R_{c1}, R_{c2}, and R_{c3} are an alkyl group such as methyl or ethyl, and R_{c4} is selected from the group consisting of alkyl such as C₄₋₁₆ alkyl, vinyl, vinyl alkyl, ω-glycidoxyalkyl such as 3-glycidoxypropyl, ω-mercaptoalkyl such as 3-mercaptopropyl, ω-acryloxyalkyl such as 3-acryloxypropyl, and ω-methacryloxyalkyl such as 3-methacryloxypropyl, among others. In a specific embodiment, the coupling agent is a compound as shown below:

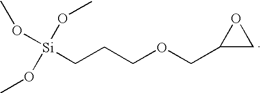

Other exemplary coupling agents comprise compounds that contain both silane and mercapto moieties, illustrative examples of which comprise mercaptomethyltriphenylsilane, beta-mercaptoethyltriphenylsilane, beta-mercaptopropltriphenyl-silane, gamma-mercaptopropyldiphenylmethyl-silane, gamma-mercaptopropylphenyldimethy;-silane, delta-mercaptobutylphenyldimethyl-silane, delta-mercaptobutyltriphenyl-silane, tris(beta-mercaptoethyl)phenylsilane, tris(gamma-mercaptopropyl)phenylsilane, tris(gamma-mercaptopropyl)methylsilane, tris(gamma-mercaptopropyl)ethylsilane, tris(gamma-mercaptopropyl)benzylsilane, and the like.

To lessen degradation of encapsulant, stabilizers such as thermal stabilizers and UV-stabilizers may be added in the encapsulant as optional component. Examples of stabilizers are described in J. F. Rabek, “Photostabilization of Polymers; Principles and Applications”, Elsevier Applied Science, NY, 1990 and in “Plastics Additives Handbook”, 5^{th} edition, edited by H. Zweifel, Hanser Publishers, 2001.

Illustrative examples of suitable stabilizers include organic phosphites and phosphonites, such as triphenyl phosphite, diphenylalkyl phosphites, phenyldialkyl phosphites, tri-(nonylphenyl)phosphite, trilauryl phosphite, trioctadecyl phosphite, di-stearyl-pentaerythritol diphosphite, tris-(2,4-di-tert-butylphenyl)phosphite, di-isodecylpentaerythritol diphosphite, di-(2,4-di-tert-butylphenyl)pentaerythritol diphosphite, tristearyl-sorbitol triphosphite, and tetrakis-(2,4-di-tert-butylphenyl)-4,4′-biphenyldiphosphonite.

Illustrative examples of suitable stabilizers include sulfur-containing phosphorus compounds such as trismethylthiophosphite, trisethylthiophosphite, trispropylthiophosphite, trispentylthiophosphite, trishexylthiophosphite, trisheptylthiophosphite, trisoctylthiophosphite, trisnonylthiophosphite, trislaurylthiophosphite, trisphenylthiophosphite, trisbenzylthiophosphite, bispropiothiomethylphosphite, bispropiothiononylphosphite, bisnonylthiomethylphosphite, bisnonylthiobutylphosphite, methylethylthiobutylphosphite, methylethylthiopropiophosphite, methylnonylthiobutylphosphite, methylnonylthiolaurylphosphite, and pentyinonylthiolaurylphosphite.

Suitable stabilizers may comprise sterically hindered phenols. Illustrative examples of sterically hindered phenol stabilizers include 2-tertiary-alkyl-substituted phenol derivatives, 2-tertiary-amyl-substituted phenol derivatives, 2-tertiary-octyl-substituted phenol derivatives, 2-tertiary-butyl-substituted phenol derivatives, 2,6-di-tertiary-butyl-substituted phenol derivatives, 2-tertiary-butyl-6-methyl- (or 6-methylene) substituted phenol derivatives, and 2,6-di-methyl-substituted phenol derivatives. In certain particular embodiments of the present invention, sterically hindered phenol stabilizers comprise alpha-tocopherol and butylated hydroxy toluene.

Suitable stabilizers include sterically hindered amines, illustrative examples of which comprise bis-(2,2,6,6-tetramethylpiperidyl-)sebacate, bis-(1,2,2,6,6-pentamethylpiperidyl) sebacate, n-butyl-3,5-di-tert-butyl-4-hydroxybenzyl malonic acid bis-(1,2,2,6,6-pentamethylpiperidyl)ester, condensation product of 1-hydroxyethyl-2,2,6,6-tetramethyl-4hydroxypiperidine and succinic acid, condensation product of N,N′-(2,2,6,6-tetramethylpiperidyl)-hexamethylene-diamine and 4-tert-octyl-amino-2,6-dichloro-s-triazine, tris-(2,2,6,6-tetramethylpiperidyl)-nitrilotriacetate, tetrakis-(2,2,6,6-tetramethyl-4-piperidyl)-1,2,3,4-butanetetracarboxylate, and 1,1′-(1,2-ethanediyl)-bis-(3,3,5,5-tetramethylpiperazinone) etc.

Suitable stabilizers include compounds which destroy peroxide, illustrative examples of which comprise esters of beta-thiodipropionic acid, for example the lauryl, stearyl, myristyl or tridecyl esters; mercaptobenzimidazole or the zinc salt of 2-mercaptobenzimidazole; zinc dibutyl-dithiocarbamate; dioctadecyl disulfide; and pentaerythritol tetrakis-(beta-dodecylmercapto)-propionate.

As a person skilled in the art can appreciate, many other optional components may be included in the encapsulant. For example, reactive or unreactive diluent (to decrease viscosity), flame retardant, mold releasing additives, flow control agents, flatting agents, wetting agents, anti-oxidant, and plasticizing additive etc., may be advantageously incorporated therein. For example, flow control, flatting agents, and wetting agents may be employed to facilitate the handling characteristics of the polymeric composition. Polymerization inhibitors and retarders may also be included to control the gel time and to enhance the handling characteristics of the polymeric composition.

In various exemplary embodiments, the amount of the siloxane-hydantoin copolymer of the invention in the encapsulant formulation is at least about 90 wt %, preferably at least about 95 wt %, and more preferably at least about 98 wt %, based on the total weight of the encapsulant formulation.

Several non-limiting examples of optoelectronic devices of the present invention are illustrated in the accompanying drawings. These figures are merely schematic representations based on convenience and the ease of demonstrating, and are, therefore, not intended to indicate relative size and dimensions of the optoelectronic devices or components thereof.

Although specific terms are used in the following description for the sake of clarity, these terms are intended to refer only to the particular structure of the embodiments selected for illustration in the drawings, and are not intended to define or limit the scope of the invention. In the drawings and the following description below, it is to be understood that like numeric designations refer to component of like function.

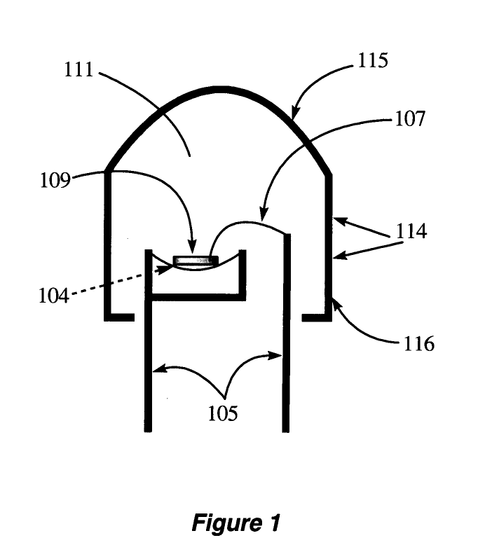

With reference to FIG. 1, a device according to one embodiment of the present invention is schematically illustrated. The device contains a LED chip 104, which is electrically connected to a lead frame 105. For example, the LED chip 104 may be directly electrically connected to an anode or cathode electrode of the lead frame 105 and connected by a lead 107 to the opposite cathode or anode electrode of the lead frame 105, as illustrated in FIG. 1. In a particular embodiment illustrated in FIG. 1, the lead frame 105 supports the LED chip 104. However, the lead 107 may be omitted, and the LED chip 104 may straddle both electrodes of the lead frame 105 with the bottom of the LED chip 104 containing contact layers, which contact both the anode and cathode electrode of the lead frame 105. The lead frame 105 connects to a power supply, such as a current or voltage source or to another circuit (not shown).

The LED chip 104 emits radiation from the radiation emitting surface 109. The LED may emit visible, ultraviolet or infrared radiation. The LED chip 104 may be any LED chip containing a p-n junction of any semiconductor layers capable of emitting the desired radiation. For example, the LED chip 104 may contain any desired Group III-V compound semiconductor layers, such as GaAs, GaAlAs, GaN, InGaN, GaP, etc., or Group II-VI compound semiconductor layers such as ZnO, ZnSe, ZnSSe, CdTe, etc., or Group IV-IV semiconductor layers, such as SiC. The LED chip 104 may also contain other layers, such as cladding layers, waveguide layers and contact layers.

The LED is packaged with an encapsulant 111 prepared according to the present invention. In one embodiment, the encapsulant 111 is used with a shell 114. The shell 114 may be any plastic or other material, such as polycarbonate, which is transparent to the LED radiation. However, the shell 114 may be omitted to simplify processing if encapsulant 111 has sufficient toughness and rigidity to be used without a shell. Thus, the outer surface of encapsulant 111 would act in some embodiments as a shell 114 or package. The shell 114 contains a light or radiation emitting surface 115 above the LED chip 104 and a non-emitting surface 116 adjacent to the lead frame 105. The radiation emitting surface 115 may be curved to act as a lens and/or may be colored to act as a filter. In various embodiments the non-emitting surface 116 may be opaque to the LED radiation, and may be made of opaque materials such as metal. The shell 114 may also contain a reflector around the LED chip 104, or other components, such as resistors, etc., if desired.

According to the present invention, the phosphor with encapsulant-matching refractive index may be coated as a thin film on the LED chip 104; or coated on the inner surface of the shell 114; or interspersed or mixed as a phosphor powder with encapsulant 111. Any suitable phosphor material according to this invention may be used with the LED chip.

While the packaged LED chip 104 is supported by the lead frame 105 according to one embodiment as illustrated in FIG. 1, the device can have various other structures. For example, the LED chip 104 may be supported by the bottom surface 116 of the shell 114 or by a pedestal (not shown) located on the bottom of the shell 114 instead of by the lead frame 105.

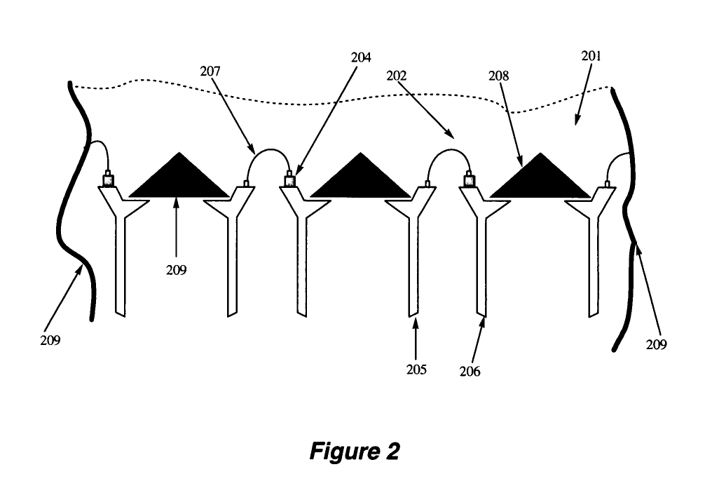

With reference to FIG. 2, a device including a LED array fabricated on a plastic substrate is illustrated. LED chips or dies 204 are physically and electrically mounted on cathode leads 206. The top surfaces of the LED chips 204 are electrically connected to anode leads 205 with lead wires 207. The lead wires may be attached by known wire bonding techniques to a conductive chip pad. The leads 206, 205 comprise a lead frame and may be made of a metal, such as silver plated copper. The lead frames and LED chip array are contained in “cavities”, “cups”, or “bowls” in a plastic package 209 (partially shown), such as a polycarbonate package, a polyvinyl chloride package or a polyetherimide package. In some embodiments, the polycarbonate comprises a bisphenol A polycarbonate. The plastic package 209 is filled with an encapsulant 201 and phosphor with encapsulant-matching refractive index (not shown) according to the present invention. The package 209 contains tapered interior sidewalls 208, which enclose the LED chips 204, and form a light spreading cavity 202, which ensures cross fluxing of LED light.

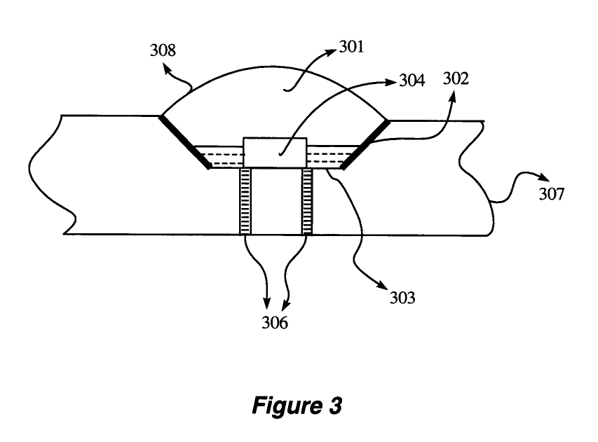

FIG. 3 shows a device wherein the LED chip 304 is supported by a carrier substrate 307. With reference to FIG. 3, the carrier substrate 307 comprises a lower portion of the LED package, and may comprise any material, such as plastic, metal or ceramic. Preferably, the carrier substrate is made out of plastic and contains a groove 303 wherein the LED chip 304 is located. The sides of the groove 303 may be coated with a reflective metal 302, such as aluminum, which acts as a reflector. However, the LED chip 304 may be formed over a flat surface of the substrate 307 as well. The substrate 307 contains electrodes 306 that electrically contact the contact layers of the LED chip 304. Alternatively, the electrodes 306 may be electrically connected to the LED chip 304 with one or two leads as illustrated in FIG. 3. The LED chip 304 is covered with an encapsulant 301 and a phosphor with encapsulant-matching refractive index (not shown) according to the present invention. If desired, a shell 308 or a glass plate may be formed over the encapsulant 301 to act as a lens or protective material.

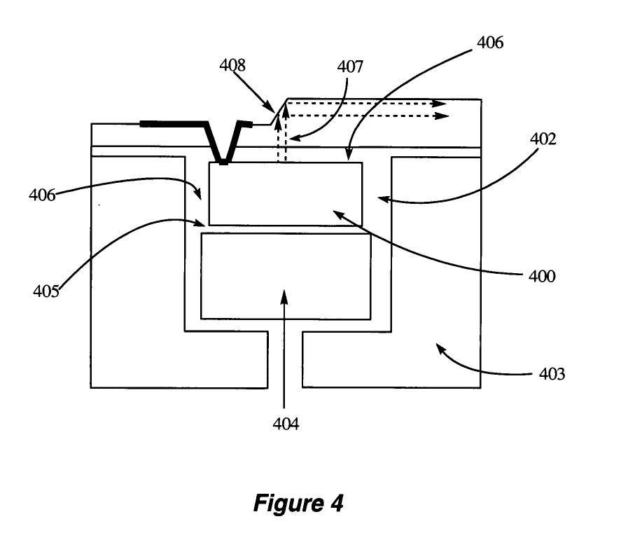

A vertical cavity surface emitting laser (VCSEL) is illustrated in FIG. 4. With reference to FIG. 4, a VCSEL 400 may be embedded inside a pocket 402 of a printed circuit board assembly 403. A heat sink 404 may be placed in the pocket 402 and the VCSEL 400 may rest on the heat sink 404. The encapsulant 406 may be formed by filling, such as injecting, an encapsulant formulation into the cavity 405 of the pocket 402 in the printed circuit board 403, which may flow around the VCSEL and encapsulate it on all sides and also form a coating top film 406 on the surface of the VCSEL 400. The top coating film 406 may protect the VCSEL 400 from damage and degradation and at the same time may also be inert to moisture, transparent and polishable. The laser beams 407 emitting from the VCSEL may strike the mirrors 408 to be reflected out of the pocket 402 of the printed circuit board 403.

The following examples are included to provide additional guidance to those skilled in the art in practicing the claimed invention. The examples provided are merely representative of the work that contributes to the teaching of the present application. Accordingly, these examples are not intended to limit the invention, as defined in the appended claims, in any manner.

### EXAMPLES

In the following example, a siloxane-hydantoin copolymer of the following formula was prepared:

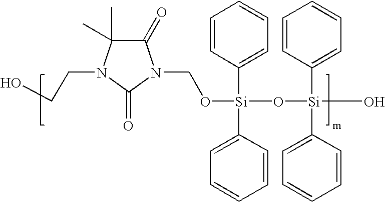

wherein m is within the range of from about 95 to about 105.

1,3-Dihydroxymethyl-5,5-dimethylhydantoin (95%, ANDAChem Inc., Shanxi China) was re-crystallized from THF and dried in vacuum to constant weight. 1,1,3,3-tetraphenyl-1,3-dichlorodisloxane (Gelest, Tullytown Pa.) was used as obtained. 9.409 g (0.05 mol) of the first co-monomer and 22.575 g (0.05 mol) of the second co-monomer were dissolved in 150 ml of absolute dimethylformamide under inert atmosphere. 12 g of dry freshly distilled triethylamine were added, and the mixture was stirred at room temperature under inert atmosphere for 2 hrs. The mixture was filtered through sintered glass filter. The filtrate was concentrated to about 70 ml, and afterwards was added dropwise to 1 liter of deionized water under vigorous stirring. White solid product was collected by filtration, was dried on glass filter with air flow, and was dissolved in 70 ml of dimethylformamide. The resulted solution was added dropwise to 1 liter of deionized water under vigorous stirring. White solid product was collected by filtration, was washed on filter with copious amount of deionized water pre-heated to 60° C., was dried on glass filter with air flow, and finally was dried overnight in vacuum oven at 50° C. 26.72 g (94.3%) of siloxane-hydantoin polymer were obtained.

Weight average molecular weight (Mw) was measured in chloroform at 30° C. using Perkin Elmer Series 200 chromatograph equipped with Varian Microgel 5 micron mixbed column and Perkin Elmer 235 UV detector; glass transition temperature (Tg) was measured with 20°/min heating rate using TA Instrument Q100 DSC calorimeter; optical transmittance of a 3 mm thick flat disk was measured using Getag Macbeth Color-Eye 7000A spectrophotometer; refractive index of a 60 nm thick film spin-coated onto silicon substrate was measured by ellipsometry.

The results were: Mw=56,500; Tg=80-85° C.; % Transmiftance at 400 nm=92%; Refractive index=1.609; and viscosity=˜1000 cps; the material flows above Tg.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All patents and publications cited herein are incorporated herein by reference.

1. A siloxane-hydantoin copolymer comprising a unit selected from the group consisting of Y¹—O_{1/2} and O_{1/2—}Y²—O_{1/2}, wherein Y¹ and Y² contain a hydantoin structure or derivative thereof.

2. The copolymer according to claim 1, which has a weight average molecular weight (Mw) within the range of from about 5,000 to about 250,000.

3. The copolymer according to claim 1, which has a glass transition temperature (Tg) within the range of from about 35° C. to about 150° C.

4. The copolymer according to claim 1, which exhibits an optical transmittance of at least 90% over radiation with wavelength in the range of from about 380 nm to about 700 nm.

5. The copolymer according to claim 1, which has a refractive index within the range of from about 1.500 to about 1.620.

6. The copolymer according to claim 1, which has a formula of:
MₐD_{b}T_{c}Q_{d}GₑH_{f}
wherein a, b, c, d, e, and f are the relative amounts of the units M, D, T, Q, G, and H respectively; a≧0; b≧0; c≧0; d≧0; e≧0; f≧0; a+b+c+d+e+f=1.0; M is R¹R²R³SiO_{1/2}; D is R⁴R⁵SiO_{2/2}; T is R⁶SiO_{3/2}; Q is SiO_{4/2}; wherein R¹, R², R³, R⁴, R⁵, and R⁶ can be each independently selected from H, hydroxyl, halo groups, monovalent acyclic hydrocarbon radicals, monovalent alicyclic hydrocarbon radicals, and monovalent aromatic hydrocarbon radicals; and
G=Y¹—O_{1/2};
H=O_{1/2}—Y²—O_{1/2};
wherein Y¹ is a monovalent group comprising one or more hydantoin structures or derivatives thereof; and Y² is a divalent group comprising one or more hydantoin structures or derivatives thereof.

7. The copolymer according to claim 6, in which the “b” value is within the range of from about 0.3 to about 0.9, and the D unit comprises: 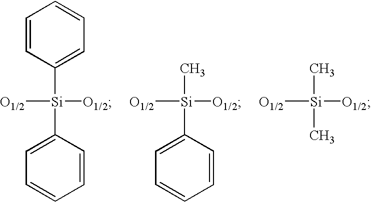
and the mixture thereof.

8. The copolymer according to claim 6, in which the “c” value is within the range of from about 0.05 to about 0.15, and the T unit comprises: 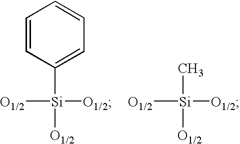
and the mixture thereof.

9. The copolymer according to claim 6, in which the “e” value is less than 0.01, and the G unit comprises a monovalent group which contains one or more hydantoin rings such as: 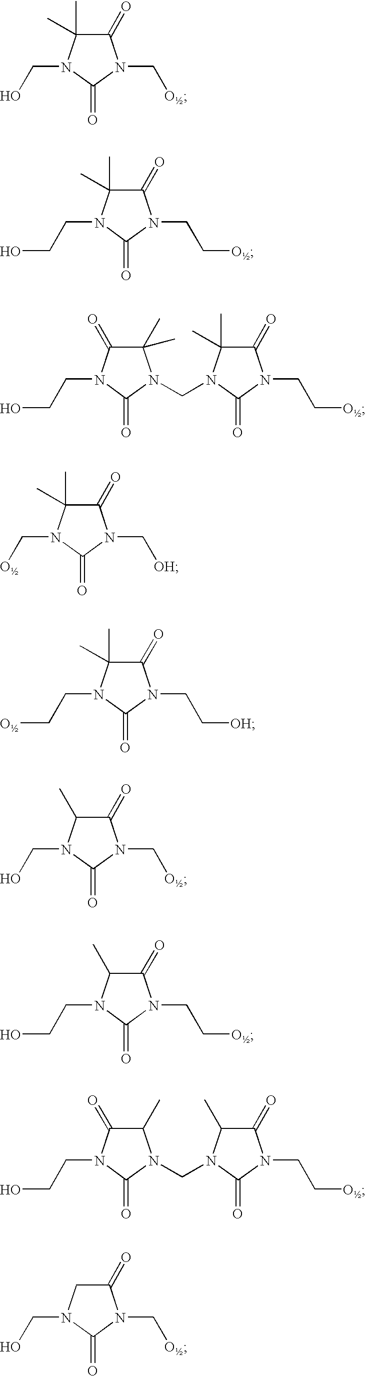 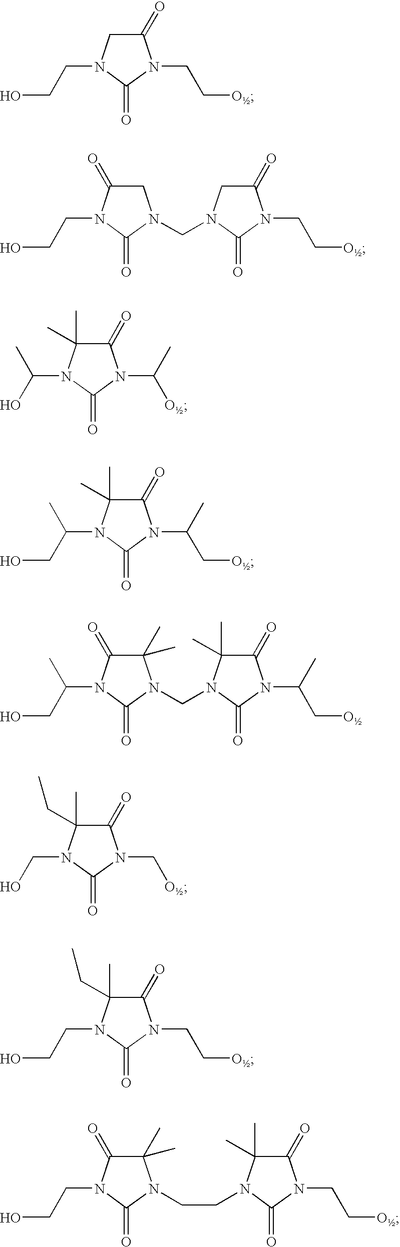
and the mixture thereof.

10. The copolymer according to claim 6, in which the “f” value is within the range of from about 0.1 to about 0.5, and the H unit comprises: 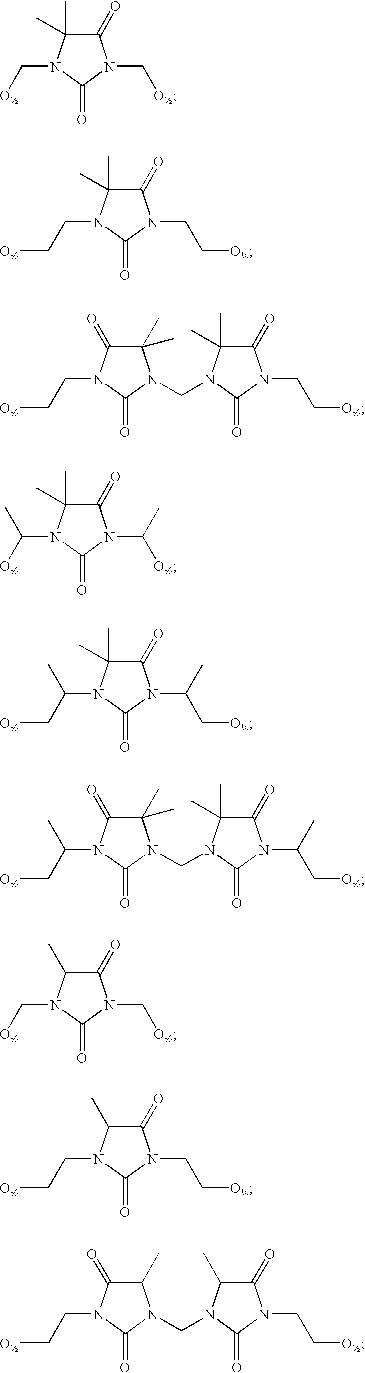 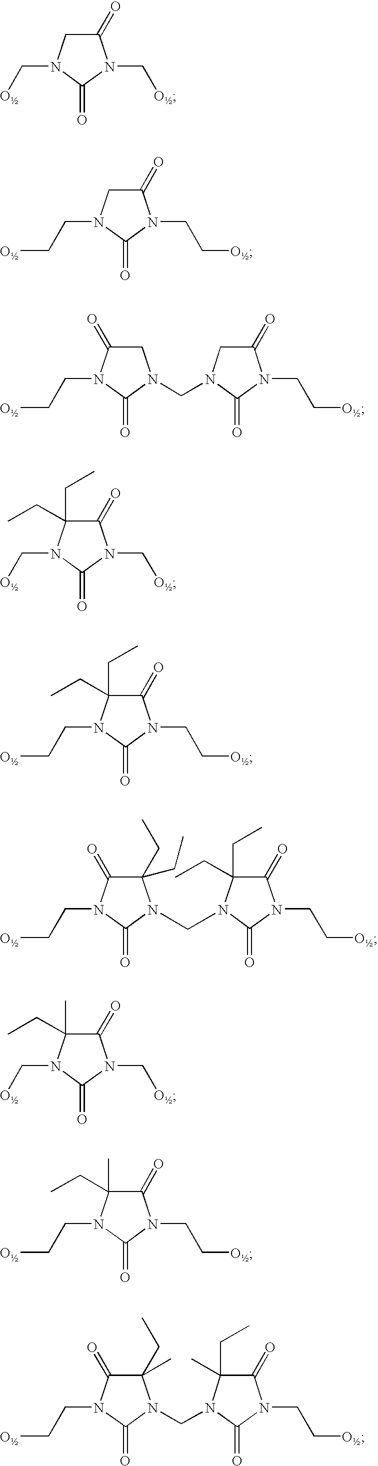
and the mixture thereof.

11. The copolymer according to claim 6, which consists essentially of “D” units and “H” units, wherein the molar ratio D:H is within the range of from about 10:1 to about 1:1.

12. The copolymer according to claim 1, which is represented by the general formula below: 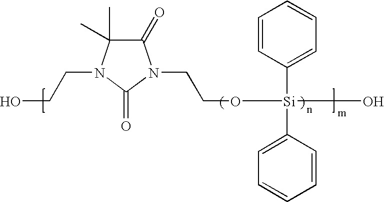
wherein n is an integer from 1 to 4; and m is within the range of from about 10 to about 500.

13. An optoelectronic device comprising a radiation source and an encapsulant, in which the encapsulant comprises a siloxane-hydantoin copolymer according to claim 1.

14. The optoelectronic device according to claim 13, in which the amount of the siloxane-hydantoin copolymer in the encapsulant formulation is at least about 90 wt %, based on the total weight of the encapsulant formulation.

15. The optoelectronic device according to claim 13, in which the radiation source is selected from a light emitting diode (LED), a lamp, a laser, an organic emissive structure, an electron gun, or any combination thereof.

16. The optoelectronic device according to claim 13, in which the radiation source is selected from UV/blue LED and laser.

17. The optoelectronic device according to claim 13, further comprising a phosphor or a blend of two or more phosphors.

18. The optoelectronic device according to claim 17, which is a white light product.

19. A method of preparing the optoelectronic device according to claim 13, which comprises:
(i) providing a radiation source, and
(ii) encapsulating the radiation source with a formulation comprising the siloxane-hydantoin copolymer according to claim 1.

20. A method of preparing the optoelectronic device according to claim 17, which comprises:
(i) providing a radiation source,
(ii) encapsulating the radiation source with the siloxane-hydantoin copolymer according to claim 1, and
(iii) disposing at least one phosphor adjacent to the radiation source, so that the phosphor is adapted to be excited by the radiation emitted from the radiation source.
